(19) United States
(12) Patent Application Publication
(10) Pub. No.: US 2012/0286329 A1
(43) Pub. Date: Nov. 15, 2012

(54) SOI FET with embedded stressor block

(75) Inventors: Kangguo Cheng, Guilderland, NY (US); Bruce B. Doris, Slingerlands, NY (US); Ali Khakifirooz, Mountain View, CA (US); Pranita Kulkarni, Slingerlands, NY (US); Ghavam G. Shahidi, Pound Ridge, NY (US)

(73) Assignee: INTERNATIONAL BUSINESS MACHINES CORPORATION, Armonk, NY (US)

(21) Appl. No.: 13/106,900

(22) Filed: May 13, 2011

(51) Int. Cl. H01L 29/06; H01L 21/336

(52) U.S. Cl. 257/190; 438/151; 257/E21.409; 257/E29.024

(57) ABSTRACT

A method and a structure are disclosed relating to strained body UTSOI FET devices. The method includes forming voids in the source/drain regions that penetrate down into the substrate below the insulating layer. The voids are epitaxially filled with a semiconductor material of a differing lattice constant than the one of the SOI layer, thus becoming a stressor block, and imparts a strain onto the FET device body.

### BACKGROUND

The present invention relates to electronic devices of very large scale integration (VLSI) circuits. In particular, it relates to the fabrication of ultra thin body semiconductor on insulator (SOI) field effect transistor (FET) high performance devices.

### BRIEF SUMMARY

A method is disclosed for fabricating ultra thin UTSOI FET devices with strain in the device bodies resulting from the fabrication of a stressor block. The method includes forming voids in the UTSOI FET source/drain regions that penetrate down into the substrate below the insulating layer. The voids are epitaxially filled with a semiconductor material of a differing lattice constant than the one of the SOI layer, thus the filling material becomes a stressor block, and imparts a strain onto the FET device body.

An UTSOI FET device structure is also disclosed. The structure has a stressor block penetrating into the semiconductor substrate underneath the insulating layer. The stressor block has a different lattice constant than the semiconductor layer, consequently it imparts a strain onto the FET device body.

### BRIEF DESCRIPTION OF THE SEVERAL VIEWS OF THE DRAWINGS

These and other features of the present invention will become apparent from the accompanying detailed description and drawings, wherein:

FIG. 1 shows a stage in the processing flow that may serve as starting point for fabricating an SOI FET with a stressor block, in a representative embodiment of the disclosure;

FIG. 2 shows voids created in a further stage in the processing flow for fabricating an SOI FET with a stressor block, in a representative embodiment of the disclosure;

FIG. 3 schematically shows a structure of an SOI FET with a stressor block, in a representative embodiment of the disclosure;

FIG. 4 shows an early stage in the processing flow for fabricating an alternate version of an SOI FET with a stressor block;

FIG. 5 shows voids created in a further stage in the processing flow for fabricating an alternate version of an SOI FET with a stressor block;

FIG. 6 shows voids filled with a stressor material in a further stage in the processing flow for fabricating an alternate version of an SOI FET with a stressor block; and

FIG. 7 schematically shows a structure of an SOI FET with a stressor block, in an alternate version of an embodiment of the disclosure.

### DETAILED DESCRIPTION

It is understood that Field Effect Transistor-s (FET) are well known in the electronic arts. Standard components of an FET are the source, the drain, the body in-between the source and the drain, and the gate, or gate-stack. The source and drain are commonly referred to a “source/drain”, especially in cases where there may be no need to distinguish between the two. In the instant disclosure the term “source/drain” will be frequently used. The gate is overlaying the body and is capable to induce a conducting channel in the body between the source and the drain. In advanced, deeply submicron, devices the source/drain are often augmented by extensions. The gate is typically separated from the body by the gate insulator. Depending whether the “on state”, or device, current is carried by electrons or holes, the FET comes as NFET or PFET. (In different nomenclature the NFET and PFET devices are often referred to as NMOS and PMOS devices.) The device current flows between the source and the drain of the device. In circuit applications individual devices are usually separated from one another both physically and electrically by isolation structures. Such isolations are well known in the art, a typical one being, for instance, a shallow trench isolation (STI).

The most common material of microelectronics is silicon (Si), or more broadly, Si based materials. Si based materials are various alloys of Si in the same basic technological content as Si. Such Si based materials of significance for microelectronics are, for instance, the alloys of Si with other elements of the IV-th group of the periodic table, Group IV elements for brevity. Known alloys formed with Ge and C are silicon germanium (SiGe), and silicon carbon (Si:C). The devices in the embodiments of the present disclosure are typically of Si, and/or of Si alloyed with Ge or C. The semiconductor materials in representative embodiments of the invention are in a single-crystalline state.

FET devices that are characterized as being silicon-on-insulator (SOI) FETs are known in the art. Such devices are formed in a layer of single crystal semiconductor material on top of an insulating layer. Typically the semiconductor material is a Si based material, often essentially pure Si. The insulating layer is typically a so called buried oxide (BOX) layer, which BOX layer, in turn, is over a silicon substrate.

As device dimension shrink, SOI FETs exhibit several commonly known advantages relative to bulk FETs. However, to maintain the electrostatic integrity of the devices, the semiconductor layer thickness has to shrink as gate length decreases. For the soon to be realized 22 nm gate length technology, and beyond, the SOI FET devices, now commonly named UTSOI, for ultra thin SOI, may have semiconductor layers on top the insulator layer of less than 100 nm of thickness.

With decreasing dimensions there is difficulty also in maintaining performance improvements with each new device generation. One approach for improving performance is to increase carrier (electron and/or hole) mobilities. A promising avenue toward better carrier mobility is to apply tensile or compressive strain in the semiconductor body regions. Typically, it may be preferable to have the body of electron conduction type devices, such as NFET, under tensile strain, while to have the body of hole conduction type devices, such as PFET, under compressive strain.

Methods of introducing strain in FET device bodies that are known in the art are loosing effectiveness for devices with as thin bodies as have to contemplated in the 22 nm, and beyond, regime. Embodiments of the present invention teach structures, and methods to fabricate such structures, that impart strain into the device bodies in spite of the extremely thin film thicknesses of the semiconductor layer that contains the device body. Representative embodiments of the present invention introduce a stressor block beneath, and as part of, the source/drain.

Manufacturing of thin device body FET structures is established in the art. It is understood that there are large number of steps involved in such processing, and each step may have practically endless variations known to those skilled in the art. For embodiments of this disclosure it is understood that the whole range of known processing techniques are available for fabricating the devices, and only those process steps will be detailed that are related to the embodiments of the present invention.

In the instant disclosure certain elements appear repeatedly in several figures. In order to avoid overcrowding not all elements are indicated on all the figures, with the understanding that the same indicator number identifies the same feature, or element, across different figures.

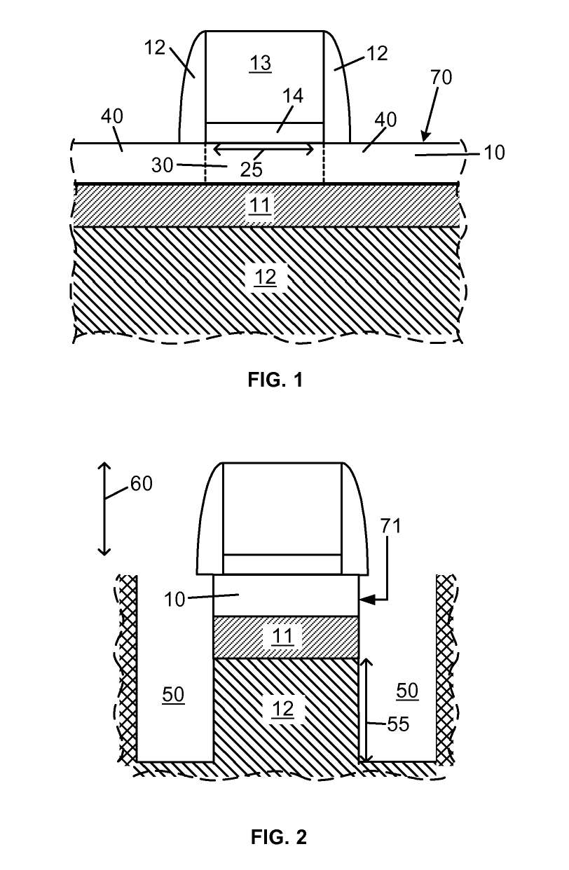

FIG. 1 shows a stage in the processing flow that may serve as starting point for fabricating an SOI FET with a stressor block, in a representative embodiment of the disclosure. The figure does not differentiate between an NFET and a PFET device, the depiction could be either type of device.

The presented embodiment for a fabrication method may commence by accepting an SOI FET fabricated to the point of completing a gate 13. The term of accepting is intended to be inclusive of any possible manner by which one may arrive at this stage of fabrication. Typically, the processing may have just reached this stage of fabrication, or samples at this stage of fabrication may have been supplied in some other manner. As it is commonly known, the gate 13 itself may be a complex structure, but such consideration has no special bearing on embodiments of the invention. Any and all gates, or gate-stacks, are included under the embodiments of the present disclosure. Same considerations apply for the gate insulator 14.

The starting device structure includes a semiconductor layer 10 of a first single crystal material having a first lattice constant. The semiconductor layer 10 may be of less than 30 nm thickness, typically in the 3 nm to 25 nm thickness range. The first single crystal material of the semiconductor layer 10 may be a Si based material. In a typical embodiment it may be essentially pure Si. The device body 30 is that portion of the semiconductor layer 10 which is underneath the gate 13. In FIG. 1 the device body 30 is shown to be roughly between the dotted lines. The source/drain regions 40 are adjacent to the gate 13, sandwiching the device body 30 in-between the two of them. The device current, symbolically noted as an arrow 25, is capable to flow between the source and drain, and it defines a length direction for the FET device.

In SOI FETs an insulator layer 11, typically a buried oxide (BOX) layer, is underneath, and is interfacing with, the semiconductor layer 10. In representative embodiments of the invention the BOX layer thickness may be between 10 nm to 150 nm. The BOX layer 11 is on top of, and supported by, a substrate 12. In a typical embodiment of the disclosure the substrate 12 is essentially Si in single crystal form. The semiconductor layer 10 has a primary surface 70 facing away from the BOX 11 layer. The device current 25 typically flows in a device channel which is in contact with the primary surface 70.

The state of processing depicted in FIG. 1 shows that sidewall spacers 12 have already been fabricated. The spacers 12 in this version of an embodiment, which is shown in FIG. 1 through 3, will be either the final spacers of the fully completed UTSOI FET, or they are of similar size to the final spacers of the fully completed ultra-thin channel silicon on insulator field effect transistor, the UTSOI FET.

The device being processed typically is part of a larger integrated circuit (IC) on a chip. This is depicted on various figures by the wavy dashed line boundaries, indicating that the drawing typically may only be a small fraction of an IC. Furthermore, such depiction of the boundaries also indicate that in typical embodiments of the invention the effects of the boundaries may be discounted. Whether the depicted FET SOI structures of the figures are bounded by isolation regions, such as an STI, or some other structure, or the substrate 12, the BOX layer 11, and the semiconductor layer 10, extend beyond the depiction, may have no consequences in regard to completion of embodiments of the present disclosure. All boundary possibilities are included.

FIG. 2 shows voids 50 created in a further stage in the processing flow for fabricating an SOI FET with a stressor block, in a representative embodiment of the disclosure. The voids 50 are being formed adjacently to the sidewall spacers 12, in, at least a portion of, the source/drain regions 40. The voids penetrate through the semiconductor layer 10, the BOX layer 11, and reach a first depth 55 in the semiconductor substrate 12. The first depth may be up to 100 nm, but typically may be between 30 nm and 80 nm. Due to the forming of the voids 50, the semiconductor layer 10 acquires side surfaces 71. This side surface 71 extends from the primary surface 70 to the BOX layer 11. As FIG. 2 depicts, the voids 50 may slightly undercut the sidewall spacers 12 by cutting into the materials below the sidewall spacers. The vertical 60 wall surface of the void 50, which is away from the gate 13 side, may the same as the one nearest to the gate 13, having exposed surfaces of the semiconductor layer 10, the BOX layer 11, and the substrate 12, and but as discussed earlier, may be the surface of some other structure. This side of the voids 50 is left unindicated in the figures, since embodiments of the invention can be completed independently of the nature of this surface which is away from the gate 13 side.

Forming such voids 50 may be done with commonly known methods, such as reactive ion etching, or various combinations of dry and wet etchings, such as with HBr gas capable of etching Si and at the same time being selective to dielectric materials, and with KaOH to etch Si.

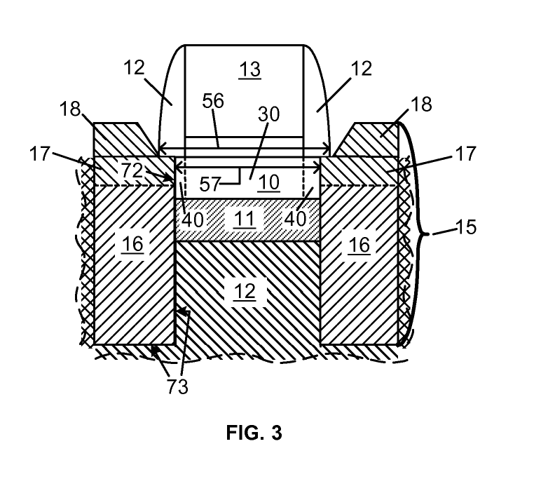

FIG. 3 schematically shows a structure of an SOI FET with a stressor block, in a representative embodiment of the disclosure. A second semiconductor single crystal material having a second lattice constant is epitaxially grown inside the voids. This second semiconductor single crystal material becomes the stressor block 15 of the SOI FET device. As the epitaxial growth progresses in filling the voids, the second semiconductor single crystal material will form a first epitaxial interface 72 with the semiconductor layer 10. The first epitaxial interface 72 includes the side surface 71 of the semiconductor layer 10.

In typical embodiments of the invention the substrate 12 is of a third single crystal material, consequently it serves as a template for seeding the second semiconductor single crystal material. The substrate 12 and the stressor block 15 share a second interface 73. The epitaxial growth of the second semiconductor single crystal material is preferably optimized to commence from the bottom of the voids on the substrate 12 material. Commencing growth from the bottom surface may be advantageous for growing with fewer defect, and for how stress is imparted to the device body 30. The bottom substrate orientation may be standard (100), with a [110] current flow 25 direction. But it may happen that due to some requirement regarding device current flow 25 direction the void surfaces have differing than standard orientations.

The reason that the epitaxially grown second semiconductor single crystal material becomes a stressor block 15 is because the second lattice constant of the second semiconductor single crystal material is chosen to be different than the first lattice constant of the first single crystal material of the semiconductor layer 10. Typically the second lattice constant also differs from the lattice constant of the substrate 12. When materials are epitaxially grown they are in matching crystalline continuity across their interfaces. Thus, the second semiconductor single crystal material of the stressor block 15 is in matching crystalline continuity across the first interface 72 with the semiconductor layer 10, and it is also in matching crystalline continuity with the substrate 12 across a second interface 73. Differing lattice constants forced to be in matching crystalline continuity across common interfaces cause strains in the materials on each side of the common interface. By appropriately choosing the lattice constants, one may generate desirable strain in the device body 30, which is part of the semiconductor layer 10.

The selection of the materials, and hence the lattice constants for the semiconductor layer 10, for the stressor block 15, and the substrate 12 depends on the device type one is dealing with. In general, however allowing for exceptions without limitations, if the stressor block 15 has a larger lattice constant than the semiconductor layer 10, the stressor block imparts a compressive strain onto the device body 30, and conversely, if the stressor block 15 has a smaller lattice constant than the semiconductor layer 10, the stressor block imparts a tensile strain onto the device body 30.

Without limitation both the semiconductor layer 10 and the substrate 12 may be of a large variety of materials, including, but without intent of limiting, Si, and Si based alloys, or other semiconductors, such as III-V, II-IV, etc, compound semiconductors.

In representative embodiments of the invention the semiconductor layer 10 and the substrate 12 are both essentially of Si. In such a case, if the SOI FET is a PFET, one may select the second semiconductor single crystal material of the stressor block 15 to be SiGe. SiGe has a larger lattice constant than Si, and consequently, it imparts a desirable compressive strain onto the PFET device body 30. The Ge content of the SiGe material may be between 10% and 60%. If the SOI FET is an NFET, one may select the second semiconductor single crystal material of the stressor block 15 to be Si:C. Si:C has a smaller lattice constant than Si, and consequently, it imparts a desirable tensile strain onto the NFET device body 30. The C content of the Si:C material may be between 0.5% and 3%.

Further referring to FIG. 3, the stressor block 15 may include, in a vertical direction 60, at least a first 16 and a second 17 segment. The vertical direction 60 is substantially perpendicular to the primary surface 70. The first segment 16 of the stressor block 15 in some embodiments is essentially free of dopants, it is in its intrinsic state. This may be desirable from point of view of device electrical behavior, such as having low parasitic capacitances. For some alternate embodiments, however, it may be advantageous to in-situ dope the first segment 16 to the opposite type than the source/drain doping. Such doping may mitigate junction leakage issues, and also to provide compatibility in the case of back gate doping, as known in the art.

The second segment 17, located above the first segment 16, is typically doped to be of the same conductivity type as the source/drain. The second segment 17 of the stressor block 15, comprises at least a portion of the source/drain in the source/drain region 40. Doping of the second segment 17 may be done in-situ during the epitaxial growth, or by implantation and annealing after the growth. Such doping is p-type for PFETs, and n-type for NFETs. Doping species examples include, for instance, for p-type: B, and for n-type: P, As, Sb.

The stressor block 15 may include a third segment 18 in the vertical direction, located above the second segment 17. This third segment 18 may have the same conductivity type as the second segment, which is that of the source/drain. The third segment 18 rises above the primary surface 70, and becomes a raised source/drain structure, as it is known in the art. The third segment 18 is instrumental in both imparting strain to the device body 30 and in lowering parasitic resistance of the source/drain.

As depicted in FIG. 3, the UTSOI FET fabrication is done regarding the implementation of the embodiment of the instant invention. Further fabrication may proceed by steps known in the art.

In the embodiment depicted in FIGS. 1 to 3, the voids 50 are formed adjacently to the sidewall spacers 12. Essentially the stressor block 15 is placed as close to the device body as it is feasible. Such positioning may be characterized by comparing certain lengths in the device, as it will now be discussed.

The gate 13 with the two sidewall spacers 12 is of a first length 56. After having fabricated the stressor block 15, the semiconductor layer 10 has a second length 57, bounded on each side by the stressor block 15. These lengths are defined in the direction in parallel with the flow of the device current 25. In the versions of the embodiments of the present disclosure depicted in FIGS. 1 to 3, the second length 57, namely the length of the semiconductor layer 10, is shorter than or approximately equal to the first length 56, namely the length of the gate 13 and the sidewall spacers 12.

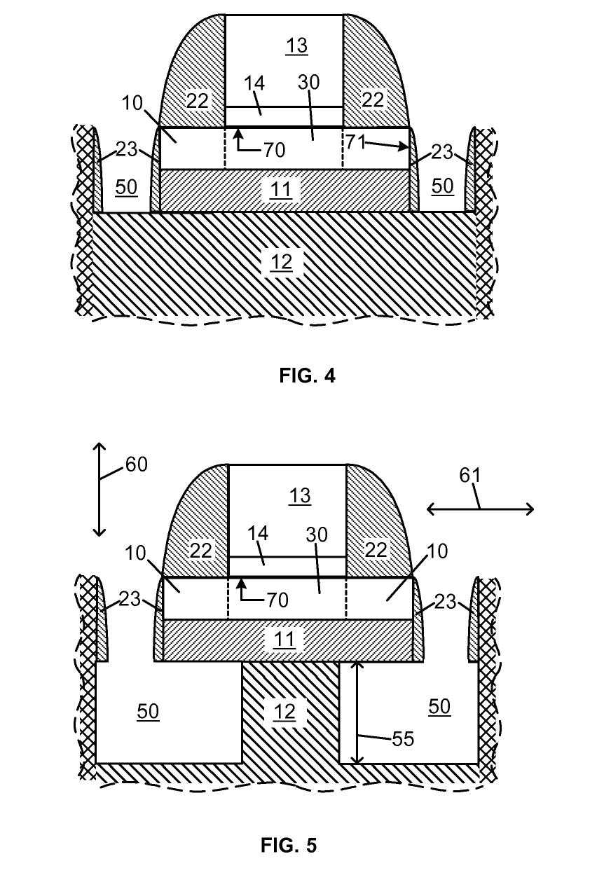

FIGS. 4 to 7 depict the processing and the structure of a different version of embodiments of the present disclosure. The difference with the version of FIGS. 1 to 3 is primarily in the length relations that have just been discussed.

The version of the embodiments of FIGS. 1 to 3 is desirable because of large imparted strain on the device body, and low parasitic source/drain resistance. But having the stressor block replacing the BOX insulator so near the device body may lead to excess junction capacitance and junction leakage. Hence the versions discussed in reference to FIGS. 4 to 7 leave a larger portion of the semiconductor layer 10 over the BOX layer 11 than the already presented versions.

In discussing the alternate version of the embodiments with reference to FIGS. 4 to 7, many of the elements, processes, and considerations are the same the ones discussed in reference to FIGS. 1 to 3. As a general course, same elements, processes, and considerations will not be introduced and discussed anew, emphasis will be given to the steps and elements that differ from the earlier presented ones.

FIG. 4 shows an early stage in the processing flow for fabricating an alternate version of an SOI FET with a stressor block. Again, an embodiment of the fabrication method presented may commence by accepting an SOI FET fabricated to the point of completing the gate 13. FIG. 4 shows the SOI FET fabrication process several steps after this acceptance. Dummy sidewall spacers 22 adjoining the gate have been formed. These dummy sidewall spacers 22 are wider than the desirable sidewall spacers 12, and they will be eventually replaced. Presently, they serve the purpose of positioning the voids 50 to adjoin the dummy sidewall spacers 22. In this manner the voids are distanced away from the device body 30 itself.

The voids are extended through the semiconductor layer 10 and the BOX layer 11 in a direction essentially vertical 60 to the primary surface 70. The forming of the voids stops upon reaching the substrate 12.

Next, auxiliary sidewall spacers 23 are formed on surfaces that have been exposed by the void, including the side surface 71 of the semiconductor layer 10. The formation of the auxiliary sidewall spacers 23 follows procedures known in the art for sidewall spacer formation.

FIG. 5 shows voids created in a further stage in the processing flow for fabricating an alternate version of an SOI FET with a stressor block. The voids 50 have continued to be extended in the direction essentially vertical 60 to the primary surface 70, until they reach a first depth 55, which may in the range of 30 nm to 100 nm. The voids 50 have also been extended underneath the BOX layer 11 in a horizontal direction 61. FIG. 3 shows this horizontal extension in the direction of the device body, possibly extending even directly below the device body 30. The amount of strain departed onto the device body 30, may also depend on how far the voids extend underneath the BOX layer 11. One may note, that the amount of strain may also depend on the density of the device neighborhood, for instance, of the gate pitch of the devices. Although the figures do not show this, the voids 50 may extend underneath the BOX layer 11 in the direction opposite to where the device body is located. While the voids 50 are extended underneath the BOX layer 11, the auxiliary sidewall spacers 23 prevent expanding the voids 50 into the semiconductor layer 10 and the BOX layer 11.

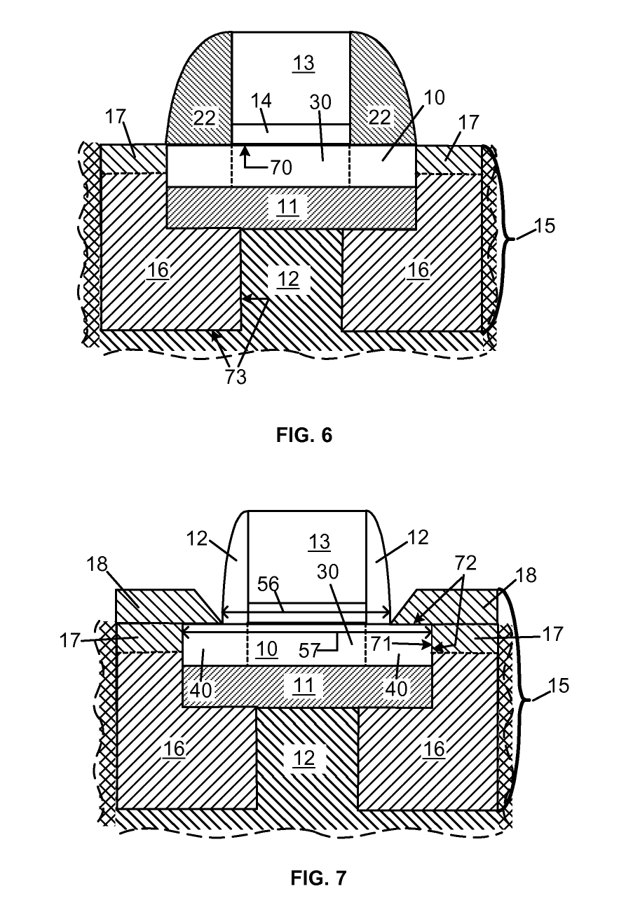

FIG. 6 shows voids filled with a stressor material in a further stage in the processing flow for fabricating an alternate version of an SOI FET with a stressor block. After the auxiliary sidewall spacers 23 have been removed, in the same manner as with the already discussed version, the voids are filled with epitaxial growth of a second semiconductor single crystal material with a second lattice constant, which becomes a stressor block 15. The considerations for selecting this second semiconductor single crystal material with a second lattice constant are the same as for the previously discussed versions. The stressor block again has at least two vertically stratified sections, an intrinsic one 16, and a doped one 17 on top of the intrinsic one. The stressor block 15 and the semiconductor layer 10 are in crystalline continuity across a first interface 72 which includes the side surface 71 of the semiconductor layer 10.

FIG. 7 schematically shows a structure of an SOI FET with a stressor block, in an alternate version of an embodiment of the disclosure. Following the processing stage shown in FIG. 6, the dummy sidewall spacers 22 are removed and replaced with new, standard width, sidewall spacers 12. The epitaxial growth may continue, and a third segment 18 of the stressor block 15, epitaxially grown over the source/drain region 40 of the semiconductor layer 10 and reaching above the principal surface may be deposited. In this manner a raised source drain is realized, and the first interface 72 between the stressor block 15 and the semiconductor layer 10 now includes not only the side surface 71, but part of the principal surface 70 of the semiconductor layer 10, as well.

In the embodiment depicted in FIGS. 4 to 7, the voids 50 were formed adjacently to the dummy sidewall spacers 22. The stressor block 15 is distanced further from the device body. Such positioning may be characterized by comparing certain lengths in the device, as it will now be discussed.

The gate 13 with the two sidewall new spacers 12 is of a first length 56. After having fabricated the stressor block 15, the semiconductor layer 10 has a second length 57, bounded on each side by the stressor block 15. These lengths are defined in the direction in parallel with the flow of the device current 25. In the versions of the embodiments of the present disclosure depicted in FIGS. 4 to 7, the second length 57, namely the length of the semiconductor layer 10, is longer than the first length 56, namely the length of the gate 13 and the new sidewall spacers 12.

As depicted in FIG. 7, the UTSOI FET fabrication is done regarding the implementation of the embodiment of the instant invention. Further fabrication may proceed by steps known in the art.

Numerical simulations have been performed to calculate the amount of strain imparted to the device body by the stressor block. These simulations show very significant strains in the device bodies. For instance, for the versions of the embodiments depicted in FIGS. 1 to 3, with pure Si semiconductor layer 10 and substrate 12, and with a 25% SiGe, 80 nm deep stressor block, 10 nm from the device body, and with 80 nm gate pitch, one obtains an over 1 GPa uniaxial compressive strain in the device body.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “under,” “upper”, “side,” “over”, “underneath” etc., as used herein refer to relative location and orientation of various portions of the structures with respect to one another, and are not intended to suggest that any particular absolute orientation with respect to external objects is necessary or required.

The foregoing specification also describes processing steps. It is understood that the sequence of such steps may vary in different embodiments from the order that they were detailed in the foregoing specification. Consequently, the ordering of processing steps in the claims, unless specifically stated, for instance, by such adjectives as “before”, “ensuing”, “after”, etc., does not imply or necessitate a fixed order of step sequence.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

1. A method, comprising:
accepting a semiconductor on insulator (SOI) FET device fabricated to the point of completing a gate, wherein said SOI FET device has a device body underneath said gate, and has source/drain regions adjacent to said gate, wherein said SOI FET device comprises a semiconductor layer of a first single crystal material having a first lattice constant and a buried oxide (BOX) layer underneath and interfacing with said semiconductor layer, wherein said semiconductor layer comprises said device body;
forming voids in at least a portion of said source/drain regions, wherein said voids penetrate through said semiconductor layer, said BOX layer, and reach a first depth in a semiconductor substrate underneath said BOX layer;
filling said voids by epitaxially growing a stressor block, wherein said stressor block is of a second semiconductor single crystal material having a second lattice constant; and
selecting said second lattice constant to be different from said first lattice constant, wherein said stressor block imparts a strain onto said device body.

2. The method of claim 1, wherein said gate is adjoined by sidewall spacers, and said semiconductor layer has a primary surface that is facing away from said BOX layer, said method further comprises:
extending said voids to said first depth in a direction essentially vertical to said primary surface, and positioning said voids to adjoin said sidewall spacers.

3. The method of claim 1, wherein said semiconductor layer has a primary surface that is facing away from said BOX layer, said method further comprises:
forming dummy sidewall spacers adjoining said gate and positioning said voids to adjoin said dummy sidewall spacers;
extending said voids through said semiconductor layer and said BOX layer in a direction essentially vertical to said primary surface; and
continue extending said void in said direction essentially vertical to said primary surface until said first depth, while also extending said void underneath said BOX layer in a horizontal direction.

4. The method of claim 3, said method further comprises forming auxiliary sidewall spacers on surfaces that have been exposed by said void, wherein said auxiliary sidewall spacers prevent expanding said void in said semiconductor layer and said BOX layer.

5. The method of claim 1, wherein said method further comprises distinguishing at least a first and a second vertical segment for said stressor block, and doping said second segment to have a same conductivity type as said source/drain, wherein said second segment is located above said first segment.

6. The method of claim 5, wherein said method further comprises keeping said first segment free of dopants.

7. The method of claim 5, wherein said method further comprises in-situ doping said first segment to have an opposite conductivity type as said source/drain.

8. The method of claim 5, wherein said method further comprises:
growing said stressor block over said semiconductor layer, wherein creating a third vertical segment for said stressor block, and doping said third segment to have said same conductivity type as said second segment.

9. The method of claim 5, wherein said method further comprises:
selecting said SOI FET to be a PFET, selecting said same conductivity type to be p-type, and selecting said second semiconductor single crystal material of said stressor block to be SiGe, wherein said strain is a compressive strain.

10. The method of claim 9, wherein said method further comprises:
selecting said first single crystal material of said semiconductor layer to be essentially Si.

11. The method of claim 5, wherein said method further comprises:
selecting said SOI FET to be an NFET, selecting said same conductivity type to be n-type, and selecting said second semiconductor single crystal material of said stressor block to be Si:C, wherein said strain is a tensile strain.

12. The method of claim 11, wherein said method further comprises:
selecting said first single crystal material of said semiconductor layer to be essentially Si.

13. A device, comprising:
a semiconductor layer of a first single crystal material having a first lattice constant, wherein said semiconductor layer is over and in direct contact with a buried oxide (BOX) layer, wherein said semiconductor layer has a primary surface and a side surface, wherein said primary surface is facing away from said BOX layer and said side surface extends from said primary surface to said BOX layer, wherein said semiconductor layer comprises a device body;
a stressor block having a first interface with said semiconductor layer, wherein said first interface comprises said side surface, wherein said stressor block is penetrating through said BOX layer to a first depth into a semiconductor substrate underneath said BOX layer, wherein said stressor block is of a second semiconductor single crystal material having a second lattice constant, and wherein said stressor block and said semiconductor layer are in matching crystalline continuity across said first interface, wherein said device body is under a strain due to said first lattice constant and said second lattice constant being different from one another; and
wherein said device is characterized as being a semiconductor on insulator (SOI) FET device capable of carrying a device current.

14. The device of claim 13, further comprising a gate with sidewall spacers, wherein said gate with sidewall spacers is having a first length and said semiconductor layer is having a second length both in a direction parallel with said device current, wherein said second length is shorter or equal than said first length.

15. The device of claim 13, further comprising a gate with sidewall spacers, wherein said gate with sidewall spacers having a first length and said semiconductor layer having a second length both in a direction parallel with said device current, wherein said second length is longer than said first length.

16. The device of claim 13, wherein said semiconductor substrate is of a third single crystal material and wherein said stressor block and said semiconductor substrate share a second interface and said stressor block and said semiconductor substrate are in matching crystalline continuity across said second interface.

17. The device of claim 16, further comprising a source/drain, wherein said stressor block comprises at least a portion of said source/drain.

18. The device of claim 17, wherein said stressor block comprises in a vertical direction at least a first and a second segment, wherein said vertical direction is substantially perpendicular to said primary surface, wherein said second segment is located above said first segment and has a same conductivity type as said source/drain.

19. The device of claim 18, wherein said first segment is essentially free of dopants.

20. The device of claim 18, wherein said first segment has an opposite conductivity type as said source/drain.

21. The device of claim 18, wherein said stressor block comprises a third segment in said vertical direction, and wherein said third segment is located above said second segment and has said same conductivity type as said second segment, and wherein said third segment rises above said primary surface.

22. The device of claim 18, wherein said SOI FET is a PFET, said same conductivity type is p-type, and said second semiconductor single crystal material of said stressor block is SiGe and said strain is compressive.

23. The device of claim 22, wherein said first single crystal material of said semiconductor layer is essentially Si.

24. The device of claim 18, wherein said SOI FET is an NFET, said same conductivity type is n-type, and said second semiconductor single crystal material of said stressor block is Si:C and said strain is tensile.

25. The device of claim 24, wherein said first single crystal material of said semiconductor layer is essentially Si.
